(19) United States
(12) Patent Application Publication
(10) Pub. No.: US 2026/0047302 A1
(43) Pub. Date: Feb. 12, 2026

(54) LIGHT EMITTING DEVICE AND ELECTRONIC APPARATUS

(71) Applicant: Sony Semiconductor Solutions Corporation, Kanagawa (JP)

(72) Inventors: Kazunori Hara, Kumamoto (JP); Takayoshi Kato, Kanagawa (JP)

(21) Appl. No.: 18/702,913

(22) PCT Filed: Nov. 15, 2022
(86) PCT No.: PCT/JP22/42416

§ 371 Date: Mar. 25, 2025

(30) Foreign Application Priority Data
Dec. 10, 2021 (JP) 2021-201231

(51) Int. Cl. H10K 59/38

(52) U.S. Cl. CPC H10K 59/38

(57) ABSTRACT

Light emitting devices with suppressed color filter peeling are disclosed. In one example, a light emitting device includes light emitting elements arranged two-dimensionally and a filter provided above the light emitting elements and including filter portions of a plurality of colors. The filter portion of at least one color of the filter portions includes a transparent resin at a bottom of the filter portion.

### TECHNICAL FIELD

The present disclosure relates to a light emitting device and an electronic apparatus including the light emitting device.

### BACKGROUND ART

Light emitting devices in which a plurality of organic light emitting diode (OLED) elements is two-dimensionally arranged are widely used. In a conventional light emitting device, a color filter is provided on a substrate different from a substrate on which the plurality of OLED elements is arranged. However, in the light emitting device having such a configuration, there is a problem that positional displacement between the light emitting element and the color filter occurs in a manufacturing step of the light emitting device, and chromaticity is easily deviated, a distance between the OLED element and the color filter is long, and utilization efficiency of light is low.

In recent light emitting devices, in order to avoid the problem described above, an on-chip color filter (OCCF) structure in which a color filter is provided on the same substrate as the OLED element has become mainstream (for example, see Patent Document 1).

### CITATION LIST

### Patent Document

Patent Document 1: Japanese Patent Application Laid-Open No. 2017-181831

### SUMMARY OF THE INVENTION

### Problems to be Solved by the Invention

However, in the light emitting device having the OCCF structure, the color filter may be peeled off. If the color filter is peeled off, there is a possibility that display characteristics of the light emitting device are deteriorated.

An object of the present disclosure is to provide a light emitting device capable of suppressing peeling of a color filter and an electronic apparatus including the light emitting device.

### Solutions to Problems

In order to solve the problems described above, a light emitting device of the present disclosure includes
a plurality of light emitting elements arranged two-dimensionally, and
a filter provided above the plurality of light emitting elements and including filter portions of a plurality of colors, in which
the filter portion of at least one color of the filter portions of the plurality of colors includes a transparent resin at a bottom of the filter portion.

A light emitting device of the present disclosure includes
a plurality of light emitting elements arranged two-dimensionally, and
a filter provided above the plurality of light emitting elements, in which
the filter includes a filter portion including a transparent resin at a bottom of the filter portion.

An electronic apparatus according to the present disclosure includes the light emitting device according to the present disclosure.

In the present disclosure, the filter portions of the plurality of colors may include filter portions of three colors. The filter portion of one color of the filter portions of the three colors may include the transparent resin at the bottom, the filter portions of two colors of the filter portions of the three colors may include the transparent resin at the bottom, or the filter portions of the three colors may include the transparent resin at the bottom.

In the present disclosure, the filter portions of the plurality of colors may include filter portions of three colors including a red filter portion, a green filter portion, and a blue filter portion.

The red filter portion of the filter portions of the three colors may include the transparent resin at the bottom, the green filter portion of the filter portions of the three colors may include the transparent resin at the bottom, or the blue filter portion of the filter portions of the three colors may include the transparent resin at the bottom.

The red filter portion and the green filter portion of the filter portions of the three colors may include the transparent resin at the bottom, the red filter portion and the blue filter portion of the filter portions of the three colors may include the transparent resin at the bottom, or the green filter portion and the blue filter portion of the filter portions of the three colors may include the transparent resin at the bottom.

The filter portions of the three colors, that is, the red filter portion, the green filter portion, and the blue filter portion may include the transparent resin at the bottoms.

In the present disclosure, the filter may include four types of filter portions including the filter portions of the three colors and an infrared transmission filter portion. One type of filter portion of the four types of filter portions may include the transparent resin at the bottom, two types of filter portions of the four types of filter portions may include the transparent resin at the bottom, three types of filter portions of the four types of filter portions may include the transparent resin at the bottom, or the four types of filter portions may include the transparent resin at the bottom.

In the present disclosure, the filter may include the four types of filter portions including the red filter portion, the green filter portion, the blue filter portion, and the infrared transmission filter portion.

The red filter portion of the four types of filter portions may include the transparent resin at the bottom, the green filter portion of the four types of filter portions may include the transparent resin at the bottom, the blue filter portion of the four types of filter portions may include the transparent resin at the bottom, or the infrared transmission filter portion of the four types of filter portions may include the transparent resin at the bottom.

The red filter portion and the green filter portion of the four types of filter portions may include the transparent resin at the bottom, the red filter portion and the blue-green filter portion of the four types of filter portions may include the transparent resin at the bottom, the red filter portion and the infrared transmission filter portion of the four types of filter portions may include the transparent resin at the bottom, the green filter portion and the blue filter portion of the four types of filter portions may include the transparent resin at the bottom, the green filter portion and the infrared transmission filter portion of the four types of filter portions may include the transparent resin at the bottom, or the blue filter portion and the infrared transmission filter portion of the four types of filter portions may include the transparent resin at the bottom.

The red filter portion, the green filter portion, and the blue filter portion of the four types of filter portions may include the transparent resin at the bottom, the red filter portion, the green filter portion, and the infrared transmission filter portion of the four types of filter portions may include the transparent resin at the bottom, the red filter portion, the blue filter portion, and the infrared transmission filter portion of the four types of filter portions may include the transparent resin at the bottom, or the green filter portion, the blue filter portion, and the infrared transmission filter portion of the four types of filter portions may include the transparent resin at the bottom.

The four types of filter portions, that is, the red filter portion, the green filter portion, the blue filter portion, and the infrared transmission filter portion may include the transparent resin at the bottoms.

In the present disclosure, the filter may include the filter portions of four colors including the red filter portion, the green filter portion, the blue filter portion, and a cyan filter portion. The filter portion of one color of the filter portions of the four colors of may include the transparent resin at the bottom, the filter portions of two colors of the filter portions of the four colors may include the transparent resin at the bottom, the filter portions of three colors of the filter portions of the four colors may include the transparent resin at the bottom, or the filter portions of the four colors may include the transparent resin at the bottom.

In the present disclosure, the filter may include the filter portions of four colors including the red filter portion, the green filter portion, the blue filter portion, and a magenta filter portion. The filter portion of one color of the filter portions of the four colors of may include the transparent resin at the bottom, the filter portions of two colors of the filter portions of the four colors may include the transparent resin at the bottom, the filter portions of three colors of the filter portions of the four colors may include the transparent resin at the bottom, or the filter portions of the four colors may include the transparent resin at the bottom.

In the present disclosure, the filter may include the filter portions of five colors including the red filter portion, the green filter portion, the blue filter portion, the cyan filter portion, and a magenta filter portion. The filter portion of one color of the filter portions of the five colors of may include the transparent resin at the bottom, the filter portions of two colors of the filter portions of the five colors may include the transparent resin at the bottom, the filter portions of three colors of the filter portions of the five colors may include the transparent resin at the bottom, the filter portions of four colors of the filter portions of the five colors may include the transparent resin at the bottom, or the filter portions of the five colors may include the transparent resin at the bottom.

In the present disclosure, the filter may include the filter portions of two colors including the cyan filter portion and the magenta filter portion. The filter portion of one color of the filter portions of the two colors may include the transparent resin at the bottom, or the filter portions of the two colors may include the transparent resin at the bottom.

In the present disclosure, some of the filter portions of the plurality of specific colors included in the display region may include the transparent resin at the bottom, or all of the filter portions of the plurality of specific colors included in the display region may include the transparent resin at the bottom.

In the present disclosure, the transparent resin may exist in a part of the bottom of the filter portion, or may exist in a substantial entirety of the bottom of the filter portion. In the present disclosure, the shape of the transparent resin is not limited, and may be, for example, a layer shape, a granular shape, or an indefinite shape. Two or more types of transparent resins may exist at the bottom of the filter portion.

### BRIEF DESCRIPTION OF DRAWINGS

FIG. 1 is a plan view illustrating an example of a configuration of a display device according to a first embodiment.

FIG. 2 is an enlarged plan view illustrating a part of a display region of the display device according to the first embodiment.

FIG. 3 is a sectional view taken along line III-III of FIG. 2.

FIG. 4 is a sectional view taken along line IV-IV of FIG. 2.

FIG. 5 is a step diagram for describing an example of a method of manufacturing the display device according to the first embodiment.

FIG. 6 is a step diagram for describing an example of the method of manufacturing the display device according to the first embodiment.

FIG. 7 is a step diagram for describing an example of the method of manufacturing the display device according to the first embodiment.

FIG. 8 is a step diagram for describing an example of the method of manufacturing the display device according to the first embodiment.

FIG. 9 is a step diagram for describing an example of the method of manufacturing the display device according to the first embodiment.

FIG. 10 is an enlarged plan view illustrating a part of a display region of a display device according to a second embodiment.

FIG. 11 is a sectional view taken along line XI-XI of FIG. 10.

FIG. 12 is a sectional view taken along line XII-XII of FIG. 10.

FIG. 13 is an enlarged plan view illustrating a part of a display region of a display device according to a third embodiment.

FIG. 14 is a sectional view taken along line XIV-XIV of FIG. 13.

FIG. 15 is an enlarged plan view illustrating a part of a display region of a display device according to a modification.

FIG. 16 is an enlarged plan view illustrating a part of a display region of a display device according to a modification.

FIG. 17A is a front view illustrating an example of an external appearance of a digital still camera. FIG. 17B is a rear view illustrating an example of an external appearance of the digital still camera.

FIG. 18 is a perspective view illustrating an example of an external appearance of a head mounted display.

FIG. 19 is a perspective view illustrating an example of an external appearance of a television apparatus.

### MODE FOR CARRYING OUT THE INVENTION

An embodiment of the present disclosure will be described in the following order with reference to the drawings. Note that the same or corresponding parts will be denoted by the same reference signs in all the drawings of the following embodiments.
1 First embodiment (Example of display device)
2 Second embodiment (Example of display device)
3. Third embodiment (Example of display device)
4 Modifications (Modifications of display device)
5 Application examples (Examples of electronic apparatus)

### 1 First Embodiment

### [Configuration of Display Device 10]

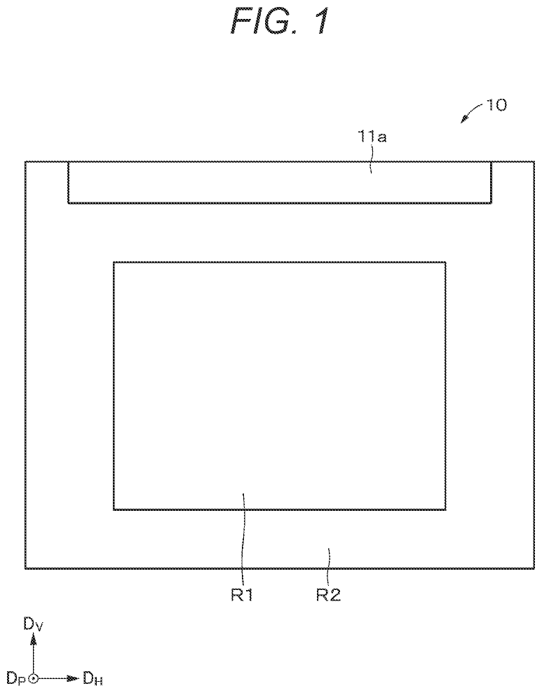

FIG. 1 is a plan view illustrating an example of a configuration of a display device 10 according to a first embodiment. The display device 10 includes a display region R1 and a peripheral region R2 provided around the display region R1. The display region R1 has a rectangular shape in plan view. In the present specification, a plan view refers to a plan view at a time when an object is viewed from a direction D_{P} perpendicular to a display surface of the display device 10 (hereinafter, referred to as a “perpendicular direction D_{P}”). In the following description, a direction parallel to a long side of the display region R1 is referred to as a horizontal direction D_{H}, and a direction parallel to a short side of the display region R1 is referred to as a vertical direction D_{V}.

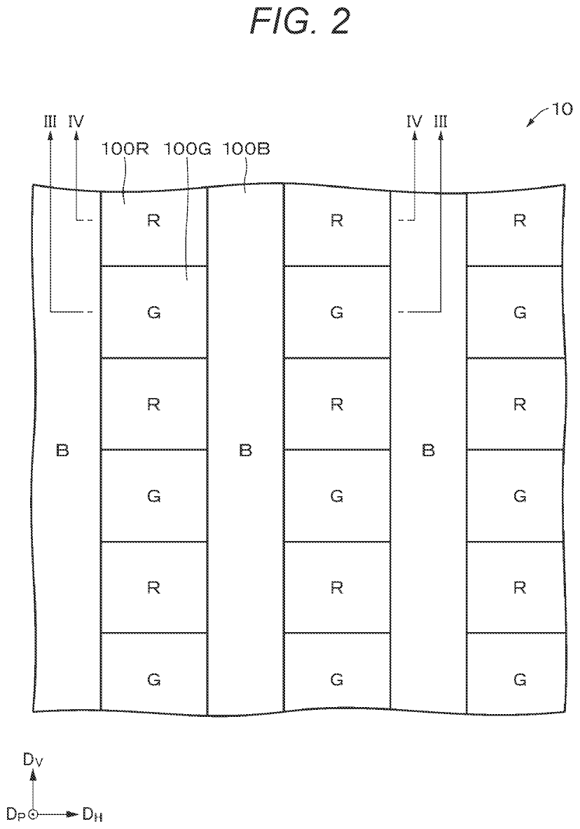

FIG. 2 is an enlarged plan view illustrating a part of the display region R1 of the display device 10 according to the first embodiment. A plurality of subpixels 100R, 100G, and 100B is two-dimensionally arranged in a prescribed arrangement pattern in the display region R1. In the peripheral region R2, a pad 11a, a driver (not illustrated) for video display, and the like are provided. A flexible printed circuit (FPC) (not illustrated) may be connected to the pad 11a.

The subpixels 100R can emit red light. The subpixels 100G can emit green light. The subpixels 100B can emit blue light. Red is an example of a first primary color among three primary colors. Green is an example of a second primary color among the three primary colors. Blue is an example of a third primary color among the three primary colors. In FIG. 2, sections denoted by symbols “R”, “G”, and “B” represent the subpixel 100R, the subpixel 100G, and the subpixel 100B, respectively.

In the following description, in a case where collectively referred to without being distinguished from one another, the subpixels 100R, 100G, and 100B will be referred to as subpixels 100. One pixel is configured by a combination of three subpixels 100R, 100G, and 100B adjacent in the horizontal direction D_{H} (row direction) of the display surface.

The subpixel 100B has a linear shape extending in the vertical direction D_{V} in plan view. The subpixels 100R and 100G have a dot shape. The subpixels 100R, 100G, and 100B have, for example, a quadrangular shape such as a rectangular shape in plan view. In the present specification, the rectangular shape includes a square shape. The subpixels 100R and 100G are alternately arranged in the vertical direction D_{V}, and constitute a column of the subpixels 100R and 100G. The column including the subpixels 100R and 100G and the linear subpixel 100B are alternately arranged in the horizontal direction D_{H}. A pixel pitch of the subpixels 100R, 100G, and 100B in the horizontal direction D_{H} is preferably 10 μm or less in order to enhance definition of the display device 10. A pixel pitch of the subpixels 100R and 100G in the perpendicular direction D_{P} is preferably 10 μm or less in order to enhance definition of the display device 10.

The display device 10 is an example of a light emitting device. The display device 10 is a top emission type OLED display device. The display device 10 may be a microdisplay. The display device 10 may be provided in a virtual reality (VR) device, a mixed reality (MR) device, an augmented reality (AR) device, an electronic view finder (EVF), a small projector, or the like.

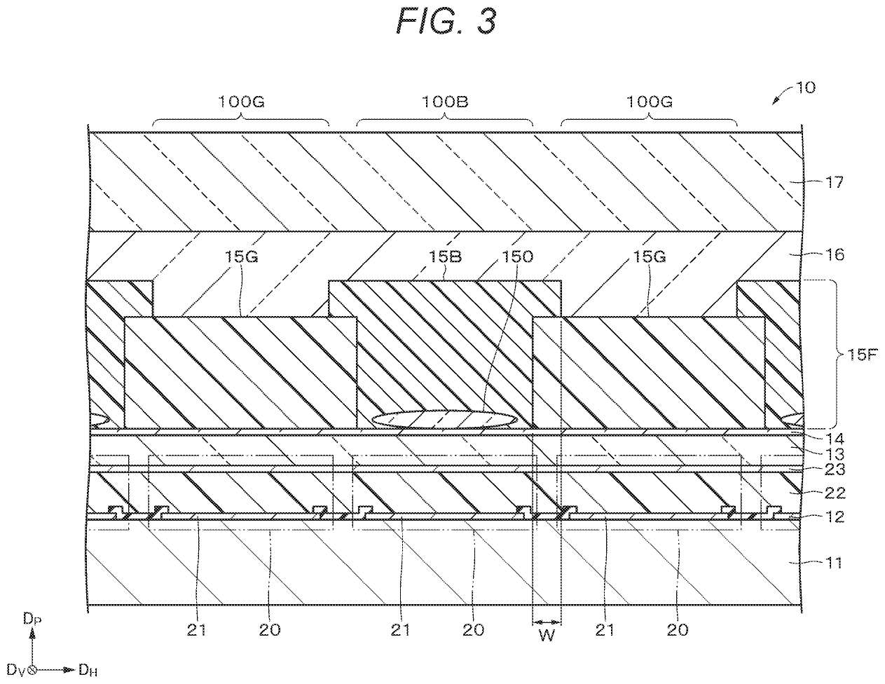

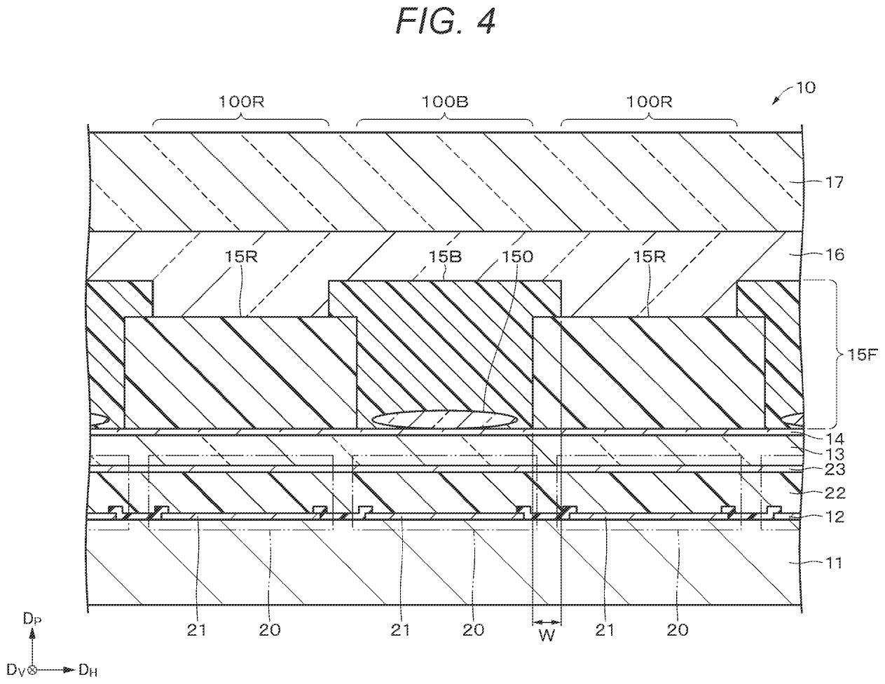

FIG. 3 is a sectional view taken along line III-III of FIG. 2. FIG. 4 is a sectional view taken along line IV-IV of FIG. 2. The display device 10 includes a circuit substrate 11, a plurality of light emitting elements 20, an insulating layer 12, a protective layer 13, a flattening layer 14, a color filter 15F, a filling resin layer 16, and a counter substrate 17. A combination of the color filter 15F and the light emitting element 20 constitutes the plurality of subpixels 100R, 100G, and 100B.

In the following description, in each layer constituting the display device 10, a surface on a top side (display surface side) of the display device 10 will be referred to as a first surface, and a surface on a bottom side (a surface opposite the display surface) of the display device 10 will be referred to as a second surface.

### (Circuit Substrate 11)

The circuit substrate 11 is what is called a backplane, and drives the plurality of light emitting elements 20. The circuit substrate 11 is provided with a drive circuit that drives the plurality of light emitting elements 20, a power supply circuit that supplies power to the plurality of light emitting elements 20, and the like (none of which is illustrated).

A substrate body of the circuit substrate 11 may be configured by, for example, a semiconductor that can be easily formed, such as a transistor, or may be configured by glass or a resin having low moisture and oxygen permeability. Specifically, the substrate body may include a semiconductor substrate, a glass substrate, a resin substrate, or the like. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one selected from the group consisting of polymethyl methacrylate, polyvinyl alcohol, polyvinyl phenol, polyethersulfone, polyimide, polycarbonate, polyethylene terephthalate, polyethylene naphthalate, and the like.

### (Light Emitting Element 20)

The light emitting element 20 is a white OLED element, and can emit white light under the control of the drive circuit and the like. The white OLED element may be a white micro-OLED (MOLED) element. As a coloring method in the display device 10, a method using a white OLED element and the color filter 15F is used.

The plurality of light emitting elements 20 is two-dimensionally arranged on the first surface of the circuit substrate 11 in a prescribed arrangement pattern such as a matrix pattern. The plurality of light emitting elements 20 includes a plurality of first electrodes 21, an OLED layer 22, and a second electrode 23 in that order on the first surface of the circuit substrate 11.

### (First Electrode 21)

The first electrode 21 is an anode. When a voltage is applied between the first electrode 21 and the second electrode 23, holes are injected from the first electrode 21 into the OLED layer 22. The first electrodes 21 are separately provided for the plurality of light emitting elements 20. The plurality of first electrodes 21 is two-dimensionally arranged on the first surface of the circuit substrate 11 in an arrangement pattern similar to the arrangement pattern of the plurality of light emitting elements 20.

The first electrode 21 may include, for example, a metal layer, or may include a metal layer and a transparent conductive oxide layer. In a case where the first electrode 21 includes a metal layer and a transparent conductive oxide layer, the transparent conductive oxide layer is preferably provided on the OLED layer 22 side in order to place a layer having a high work function adjacent to the OLED layer 22.

The metal layer also has a function as a reflective layer that reflects light emitted from the OLED layer 22. The metal layer includes, for example, at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

A base layer (not illustrated) may be provided adjacent to the second surface side of the metal layer. The base layer is for improving crystal orientation of the metal layer at a time of forming the metal layer. The base layer includes, for example, at least one metal element selected from the group consisting of titanium (Ti) and tantalum (Ta). The base layer may include the at least one metal element described above as a constituent element of an alloy.

The transparent conductive oxide layer includes a transparent conductive oxide. The transparent conductive oxide includes, for example, at least one selected from the group consisting of a transparent conductive oxide including indium (hereinafter referred to as an “indium-based transparent conductive oxide”), a transparent conductive oxide including tin (hereinafter referred to as a “tin-based transparent conductive oxide”), and a transparent conductive oxide including zinc (hereinafter referred to as a “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO) or fluorine-doped indium oxide (IFO). Among the above transparent conductive oxides, the indium tin oxide (ITO) is particularly preferable. This is because the indium tin oxide (ITO) has a particularly low barrier for hole injection into the OLED layer 22 in terms of a work function, and thus, the drive voltage of the display device 10 can be particularly reduced. The tin-based transparent conductive oxide includes, for example, tin oxide, antimony-doped tin oxide (ATO), or fluorine-doped tin oxide (FTO). The zinc-based transparent conductive oxide includes, for example, zinc oxide, aluminum-doped zinc oxide (AZO), boron-doped zinc oxide, or gallium-doped zinc oxide (GZO).

### (OLED Layer 22)

The OLED layer 22 is an example of an organic layer including a light emitting layer. The OLED layer 22 can emit white light by recombination of holes injected from the first electrode 21 and electrons injected from the second electrode 23.

The OLED layer 22 is provided between the plurality of first electrodes 21 and the second electrode 23. The OLED layer 22 is continuously provided over the plurality of light emitting elements 20 in the display region R1, and is shared by the plurality of light emitting elements 20 in the display region R1.

The OLED layer 22 may be an OLED layer including a single-layer light emitting unit, may be an OLED layer including two layers of light emitting units (tandem structure), or may be an OLED layer having another structure. The OLED layer having a single-layer light emitting unit has a configuration in which, for example, a hole injection layer, a hole transport layer, a red light emitting layer, a light emission separation layer, a blue light emitting layer, a green light emitting layer, an electron transport layer, and an electron injection layer are stacked on one another in that order from the first electrodes 21 toward the second electrode 23. The OLED layer including a two-layer light emitting unit has a configuration in which, for example, a hole injection layer, a hole transport layer, a blue light emitting layer, an electron transport layer, a charge generation layer, a hole transport layer, a yellow light emitting layer, an electron transport layer, and an electron injection layer are stacked on one another in that order from the first electrodes 21 to the second electrode 23.

The hole injection layer is for enhancing hole injection efficiency of each light emitting layer and suppressing leakage. The hole transport layer is for enhancing hole transport efficiency of each light emitting layer. The electron injection layer is for enhancing electron injection efficiency of each light emitting layer. The electron transport layer is for enhancing electron transport efficiency of each light emitting layer. The light emission separation layer is a layer for adjusting injection of carriers into each light emitting layer, and light emission balance of each color is adjusted by injecting electrons or holes into each light emitting layer via the light emission separation layer. The charge generation layer supplies electrons and holes to two light emitting layers sandwiching the charge generation layer.

When an electric field is applied to the red light emitting layer, the green light emitting layer, the blue light emitting layer, and the yellow light emitting layer, holes injected from the first electrodes 21 or the charge generation layer and electrons injected from the second electrode 23 are recombined together, and red light, green light, blue light, and yellow light are generated, respectively.

### (Second Electrode 23)

The second electrode 23 is a cathode. When a voltage is applied between the first electrode 21 and the second electrode 23, electrons are injected from the second electrode 23 into the OLED layer 22. The second electrode 23 is a transparent electrode having transparency to visible light. In the present specification, visible light refers to light in a wavelength range of 360 nm or more and 830 nm. The second electrode 23 is provided on the first surface of the OLED layer 22. The second electrode 23 is continuously provided over the plurality of light emitting elements 20 in the display region R1, and is shared by the plurality of light emitting elements 20 in the display region R1.

The second electrode 23 preferably includes a material having as high transmissivity as possible and a small work function, in order to enhance luminous efficiency. The second electrode 23 includes, for example, at least one of a metal layer or a transparent conductive oxide layer. Specifically, the second electrode 23 includes a single layer film of a metal layer or a transparent conductive oxide layer, or a multilayer film of the metal layer and the transparent conductive oxide layer. In a case where the second electrode 23 includes a multilayer film, the metal layer may be provided on the OLED layer 22 side or the transparent conductive oxide layer may be provided on the OLED layer 22 side, but in order to place a layer having a low work function adjacent to the OLED layer 22, the metal layer is preferably provided on the OLED layer 22 side.

The metal layer includes, for example, at least one metal element selected from the group consisting of magnesium (Mg), aluminum (Al), silver (Ag), calcium (Ca), and sodium (Na). The metal layer may include the at least one metal element described above as a constituent element of an alloy. Specific examples of the alloy include an Mg—Ag alloy, an Mg—Al alloy, and an Al—Li alloy. The transparent conductive oxide layer includes a transparent conductive oxide. As the transparent conductive oxide, a material similar to the transparent conductive oxide of the first electrode 21 described above can be exemplified.

### (Insulating Layer 12)

The insulating layer 12 insulates between the adjacent first electrodes 21. The insulating layer 12 is provided in a portion between the separated first electrodes 21 on the first surface of the circuit substrate 11. The insulating layer 12 has a plurality of openings 12a. Each of the plurality of openings 12a is provided for a corresponding one of light emitting elements 20. Specifically, each of the plurality of openings 12a is provided on the first surface (a surface on the OLED layer 22 side) of each first electrode 21. The first electrodes 21 and the OLED layer 22 are in contact with each other through the openings 12a.

The insulating layer 12 may be an organic insulating layer, an inorganic insulating layer, or a multilayer body of the organic insulating layer and the inorganic insulating layer. The organic insulating layer includes, for example, at least one selected from the group consisting of a polyimide resin, an acrylic resin, a novolac resin, and the like. The inorganic insulating layer includes, for example, at least one selected from the group consisting of silicon oxide (SiOₓ), silicon nitride (SiNₓ), silicon oxynitride (SiOₓN_{y}), and the like.

### (Protective Layer 13)

The protective layer 13 has transparency to visible light. The protective layer 13 is provided on the first surface of the second electrode 23, and covers the plurality of light emitting elements 20. The protective layer 13 shields the light emitting element 20 from the outside air, and suppresses moisture infiltration into the light emitting element 20 from the external environment. Furthermore, in a case where the second electrode 23 includes a metal layer, the protective layer 13 may have a function of suppressing oxidation of the metal layer.

The protective layer 13 includes, for example, an inorganic material or a polymer resin having low hygroscopicity. The protective layer 13 may have a single layer structure or a multilayer structure. In a case where a thickness of the protective layer 13 is increased, the protective layer 13 preferably has a multilayer structure. This is for alleviating an internal stress in the protective layer 13. The inorganic material includes, for example, at least one selected from the group consisting of silicon oxide (SiOₓ), silicon nitride (SiNₓ), silicon oxynitride (SiOₓN_{y}), titanium oxide (TiOₓ), aluminum oxide (AlOₓ), and the like. The polymer resin includes, for example, at least one selected from the group consisting of a thermosetting resin, an ultraviolet curable resin, and the like. Specifically, the polymer resin includes, for example, at least one selected from the group consisting of an acrylic resin, a polyimide resin, a novolac resin, an epoxy resin, a norbornene resin, and the like.

### (Flattening Layer 14)

The flattening layer 14 is provided on the first surface of the protective layer 13, and flattens unevenness of the first surface of the protective layer 13. The flattening layer 14 includes, for example, an inorganic material or a polymer resin. As the inorganic material, a material similar to the material of the protective layer 13 can be exemplified. As the polymer resin, a material similar to the material of the protective layer 13 can be exemplified.

### (Color Filter 15F)

The color filter 15F is an on-chip color filter (OCCF). The color filter 15F is provided above the plurality of light emitting elements 20. Specifically, the color filter 15F is provided on the first surface of the flattening layer 14. The color filter 15F includes, for example, a plurality of red filter portions 15R, a plurality of green filter portions 15G, and a plurality of blue filter portions 15B. Note that, in the first embodiment, in a case where collectively referred to without being distinguished from one another, the red filter portions 15R, the green filter portions 15G, and the blue filter portions 15B will be collectively referred to as filter portions 15.

The plurality of filter portions 15 is two-dimensionally arranged in an in-plane direction. In the present specification, the in-plane direction means a direction parallel to the first surface of the circuit substrate 11. Each filter portion 15 is provided above one of the light emitting elements 20. The subpixel 100R includes the red filter portion 15R and the light emitting element 20. The subpixel 100G includes the green filter portion 15G and the light emitting element 20. The subpixel 100B includes the blue filter portion 15B and the light emitting element 20.

The red filter portions 15R transmit red light out of the white light emitted from the light emitting elements 20 and absorb light other than the red light. The green filter portions 15G transmit green light out of the white light emitted from the light emitting elements 20 and absorb light other than the green light. The blue filter portions 15B transmit blue light out of the white light emitted from the light emitting elements 20 and absorb light other than the blue light.

The blue filter portion 15B has a linear shape extending in the vertical direction D_{V} in plan view, similarly to the subpixel 100B. Similarly to the subpixel 100R and the subpixel 100G, the red filter portion 15R and the green filter portion 15G have a dot shape in plan view. The red filter portion 15R and the green filter portion 15G have, for example, a quadrangular shape such as a rectangular shape in plan view.

At least one filter portion 15 of the blue filter portion 15B, the green filter portion 15G, or the red filter portion 15R includes a transparent resin 150 at a bottom of the filter portion 15. Specifically, for example, the filter portion 15 of one color of the blue filter portion 15B, the green filter portion 15G, or the red filter portion 15R may include the transparent resin 150 at the bottom of the filter portion 15, the filter portions 15 of two colors of the blue filter portion 15B, the green filter portion 15G, or the red filter portion 15R may include the transparent resin 150 at the bottom of the filter portion 15, and all of the blue filter portion 15B, the green filter portion 15G, and the red filter portion 15R may include the transparent resin 150 at the bottom of the filter portion 15. The filter portion 15 may include the transparent resin 150 in a part of the bottom of the filter portion 15, or may include the transparent resin 150 in a substantial entirety of the bottom of the filter portion 15.

FIGS. 3 and 4 illustrate an example in which the blue filter portion 15B includes the transparent resin 150 at the bottom of the blue filter portion 15B. The transparent resin 150 may extend over the plurality of light emitting elements 20 in the vertical direction D_{V}, or may be divided between adjacent light emitting elements 20. The transparent resin 150 bonds the bottom of the color filter 15F and the flattening layer 14 together, and can suppress peeling of the color filter 15F from the flattening layer 14. The transparent resin 150 preferably has transparency to visible light. Since the transparent resin 150 has transparency to visible light, the white light emitted from the light emitting elements 20 can be prevented from being absorbed by the transparent resin 150. Therefore, it is possible to suppress a decrease in luminance of the display device 10.

The transparent resin 150 may have a layer shape. That is, the transparent resin 150 may form a transparent resin layer on the bottom of the filter portion 15. However, the transparent resin 150 is not required to have a layer shape, and may have a granular shape, an indefinite shape, or the like. For example, the filter portion 15 may include one or a plurality of transparent resins 150 having a granular shape at the bottom, or may include one or a plurality of transparent resins 150 having an indefinite shape. The filter portion 15 may include at least one selected from the group consisting of the transparent resin 150 having a layer shape, the transparent resin 150 having a granular shape, and the transparent resin 150 having an indefinite shape at the bottom. The transparent resin 150 preferably includes a thermosetting resin. The thermosetting resin includes, for example, a thermosetting organic resin such as an epoxy resin.

The transparent resin 150 and the filling resin layer 16 preferably include materials having the same component. Since the transparent resin 150 and the filling resin layer 16 include a material having the same component, the transparent resin 150 permeates the color filter 15F and is cured to form the filling resin layer 16, and thus, the transparent resin 150 can exist at the bottom of the color filter 15F. That is, the color filter 15F and the flattening layer 14 can be bonded to each other by the transparent resin 150.

The materials having the same component described above preferably include a thermosetting resin. The thermosetting resin includes, for example, a thermosetting organic resin such as an epoxy resin. Since the material of the same component described above includes a thermosetting resin, the thermosetting resin for forming the filling resin layer 16 permeates the color filter 15F and is cured in a baking step described later so that the transparent resin 150 can exist at the bottom of the color filter 15F. That is, the color filter 15F and the flattening layer 14 can be bonded to each other by the transparent resin 150.

Peripheral edges of the adjacent filter portion 15 may overlap each other. The filter portion 15 located on an upper side in the overlapping of the peripheral edges preferably includes the transparent resin 150 at the bottom. The filter portion 15 located on the upper side in the overlapping of the peripheral edges is more likely to be peeled off in the baking step described later than the filter portion 15 located on a lower side in the overlapping of the peripheral edges. Therefore, in order to suppress peeling of the color filter 15F by the transparent resin 150, the filter portion 15 located on the upper side in the overlapping of the peripheral edges preferably includes the transparent resin 150 at the bottom. In the present specification, the peripheral edge of the filter portion 15 refers to a region having a predetermined width from the peripheral edge of the filter portion 15 toward inside.

For example, as illustrated in FIG. 3, the peripheral edge of the blue filter portion 15B and the peripheral edge of the green filter portion 15G may overlap each other in the horizontal direction D_{H}. The peripheral edge of the blue filter portion 15B may be located on the upper side of the peripheral edge of the green filter portion 15G in the horizontal direction D_{H}. In this case, since the blue filter portion 15B is more likely to be peeled than the green filter portion 15G in the baking step described later, the peripheral edge of the blue filter portion 15B preferably includes the transparent resin 150 at the bottom.

For example, as illustrated in FIG. 4, the peripheral edge of the blue filter portion 15B and the peripheral edge of the red filter portion 15R may overlap each other in the horizontal direction D_{H}. The peripheral edge of the blue filter portion 15B may be located on the upper side of the peripheral edge of the red filter portion 15R in the horizontal direction D_{H}. In this case, since the blue filter portion 15B is more likely to be peeled than the red filter portion 15R in the baking step described later, the peripheral edge of the blue filter portion 15B preferably includes the transparent resin 150 at the bottom.

For example, the peripheral edge of the red filter portion 15R and the peripheral edge of the green filter portion 15G may overlap each other in the vertical direction D_{V}. The peripheral edge of the red filter portion 15R may be located on the upper side of the peripheral edge of the green filter portion 15G in the vertical direction D_{V}. In this case, since the red filter portion 15R is more likely to be peeled than the green filter portion 15G in the baking step described later, the peripheral edge of the red filter portion 15R preferably includes the transparent resin 150 at the bottom.

An overlapping width W of the peripheral edges of the adjacent filter portions 15 is preferably 0.1 μm or more and 0.5 μm or less. However, the overlapping width W of the filter portions 15 may exceed 0.5 μm. Note that, in a case where the overlapping width of the peripheral edges varies depending on the position, a maximum value of the overlapping width of the peripheral edges is set as the overlapping width W of the peripheral edges.

The red filter portion 15R includes, for example, a red colorant and an ultraviolet curable resin. The red colorant includes, for example, at least one selected from the group consisting of a red dye and a red pigment. The green filter portion 15G includes, for example, a green colorant and an ultraviolet curable resin. The green colorant includes, for example, at least one selected from the group consisting of a green dye and a green pigment. The blue filter portion 15B includes, for example, a blue colorant and an ultraviolet curable resin. The blue colorant includes, for example, at least one selected from the group consisting of a blue dye and a blue pigment.

### (Filling Resin Layer 16)

The filling resin layer 16 is provided between the color filter 15F and the counter substrate 17. The filling resin layer 16 has a function as an adhesive layer for bonding the color filter 15F and the counter substrate 17. The filling resin layer 16 includes, for example, a thermosetting resin. The thermosetting resin is preferably a transparent resin. The transparent resin preferably includes a material having the same component as the transparent resin 150 included at the bottom of the filter portion 15. The thermosetting resin includes, for example, a thermosetting organic resin such as an epoxy resin. The filling resin layer 16 may further include an ultraviolet curable resin.

### (Counter Substrate 17)

The counter substrate 17 seals the light emitting element 20, the color filter 15F, and the like. The counter substrate 17 has transparency to visible light, for example. The counter substrate 17 is provided on the first surface of the filling resin layer 16 and faces the circuit substrate 11. The counter substrate 17 is, for example, a glass substrate.

### [Method of Manufacturing Display Device 10]

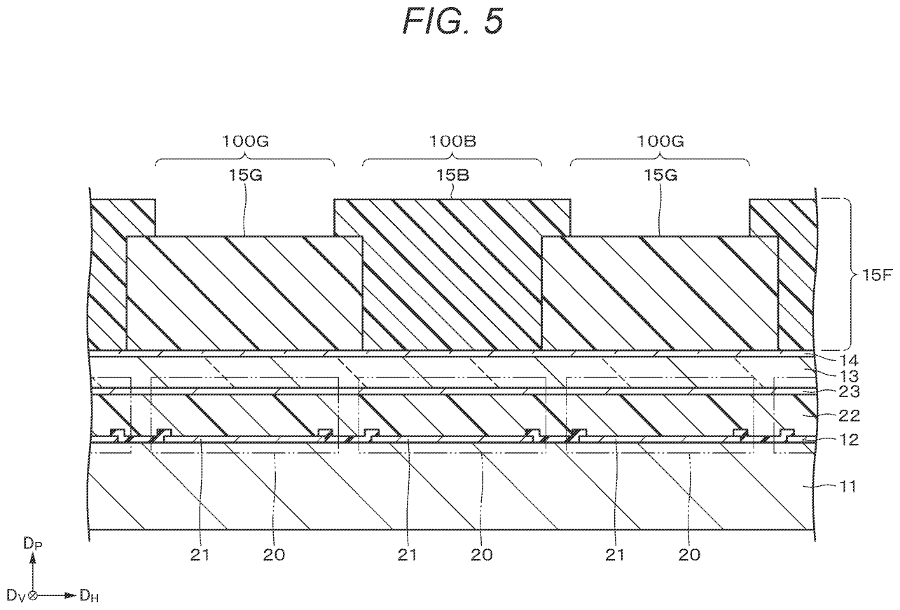

An example of a method of manufacturing the display device 10 according to the first embodiment will be described with reference to FIGS. 5 to 9.

### (Step of Forming First Electrode 21)

First, a metal layer and a metal oxide layer are sequentially formed on the first surface of the circuit substrate 11 by, for example, a sputtering method, and then the metal layer and the metal oxide layer are patterned by using, for example, a photolithography technique and an etching technique. The plurality of first electrodes 21 is thus formed on the first surface of the circuit substrate 11.

### (Step of Forming Insulating Layer 12)

Next, the insulating layer 12 is formed on the first surface of the circuit substrate 11 so as to cover the plurality of first electrodes 21 by, for example, a chemical vapor deposition (CVD) method. Next, the opening 12a is formed in a portion of the insulating layer 12 located on the first surface of each of the first electrodes 21 by, for example, a photolithography technique and a dry etching technique.

### (Step of Forming OLED Layer 22)

Next, a hole transport layer, a red light emitting layer, a light emission separation layer, a blue light emitting layer, a green light emitting layer, an electron transport layer, and an electron injection layer are stacked in that order on the first surfaces of the plurality of first electrodes 21 and on the first surface of the insulating layer 12 by, for example, a vapor deposition method, to form the OLED layer 22.

### (Step of Forming Second Electrode 23)

Next, the second electrode 23 is formed on the first surface of the OLED layer 22 by, for example, the vapor deposition method or the sputtering method. The plurality of light emitting elements 20 is thus formed on the first surface of the circuit substrate 11.

### (Step of Forming Protective Layer 13)

Next, the protective layer 13 is formed on the first surface of the second electrode 23 by, for example, the CVD method or the vapor deposition method.

### (Step of Forming Flattening Layer 14)

Next, the flattening layer 14 is formed on the first surface of the second electrode 23 by, for example, the CVD method or the vapor deposition method.

### (Step of Forming Color Filter 15F)

Next, a coloring composition for forming a green filter portion is applied onto the first surface of the flattening layer 14, and after pattern exposure by irradiation with ultraviolet rays through a photomask, development is performed to form the green filter portion 15G. Next, a coloring composition for forming a red filter portion is applied onto the first surface of the flattening layer 14, and after pattern exposure by irradiation with ultraviolet rays through a photomask, development is performed to form the red filter portion 15R. Next, a coloring composition for forming a blue filter portion is applied onto the first surface of the flattening layer 14, and after pattern exposure by irradiation with ultraviolet rays through a photomask, development is performed to form the blue filter portion 15B. As a result, as illustrated in FIG. 5, the color filter 15F is formed on the first surface of the flattening layer 14.

### (Step of Superimposing Counter Substrate 17)

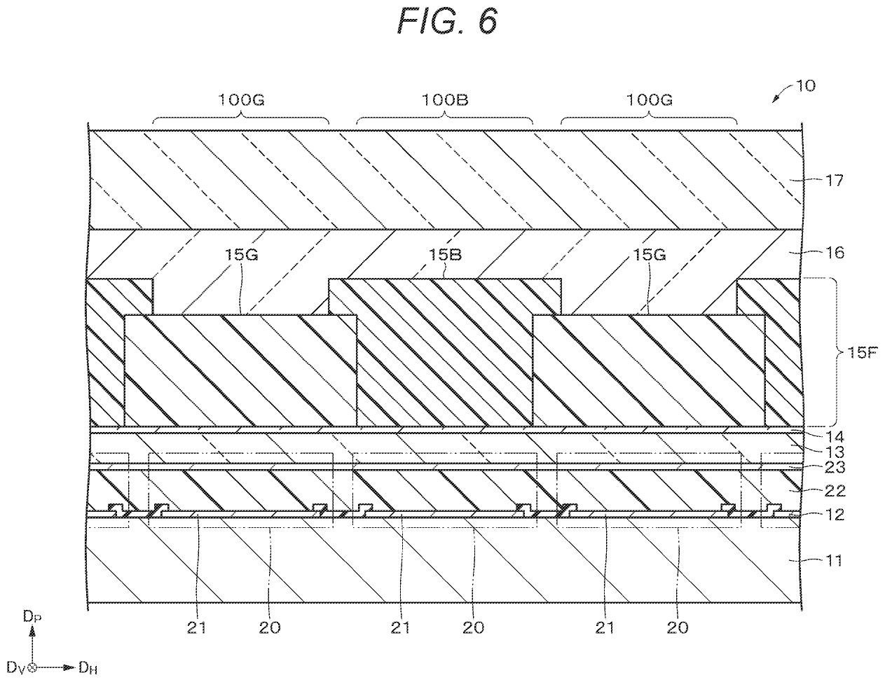

Next, as illustrated in FIG. 6, the color filter 15F is covered with the filling resin layer 16 by using, for example, a one drop fill (ODF) method, and then the counter substrate 17 is superimposed on the filling resin layer 16.

### (Baking Step)

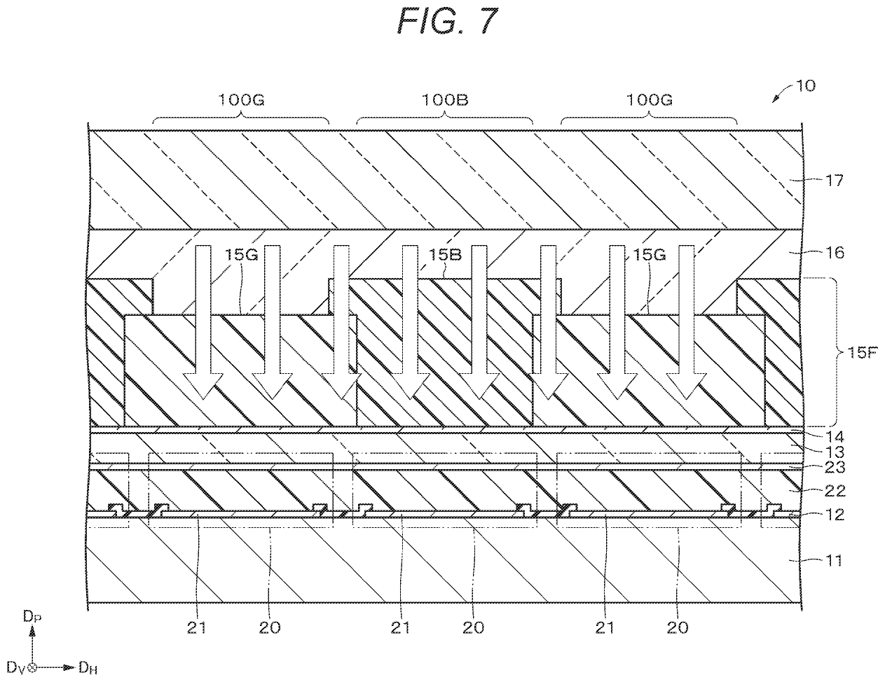

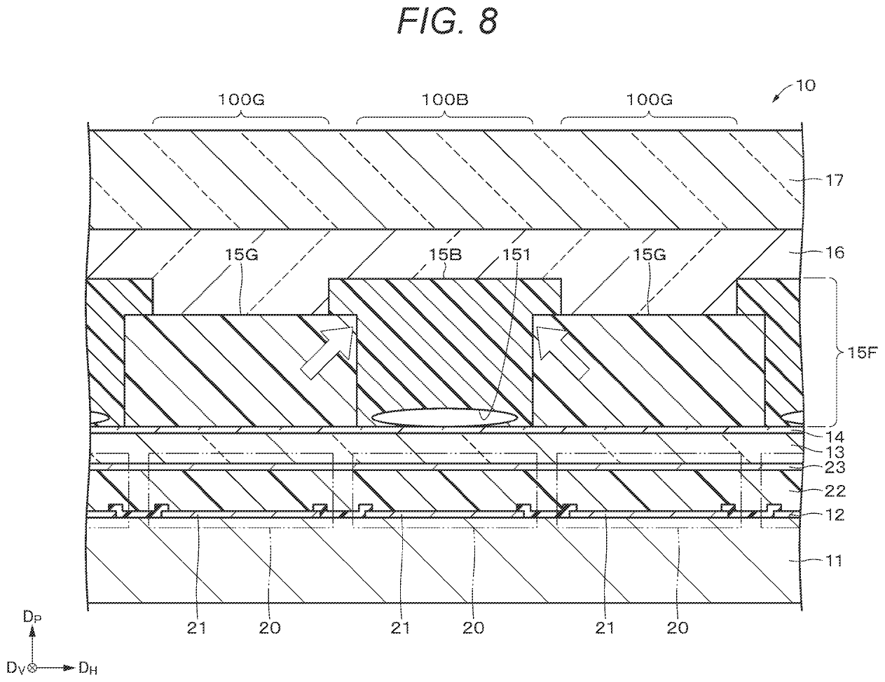

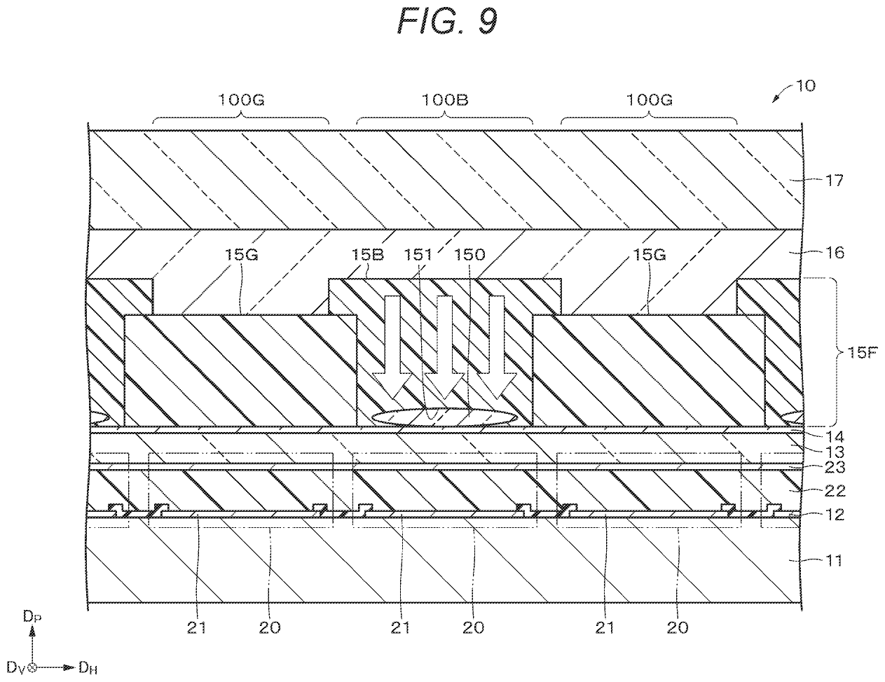

Next, when the baking step is started, as illustrated in FIG. 7, then, the thermosetting resin included in the filling resin layer 16 starts to permeate the color filter 15F. The thermosetting resin is preferably a transparent resin. Since the blue filter portion 15B is located on the upper side of the green filter portion 15G in the overlapping of the peripheral edges in the horizontal direction D_{H}, when the baking step is started, as illustrated in FIG. 8, stress (see arrows in FIG. 8) is likely to be applied from the green filter portion 15G to the blue filter portion 15B in such a direction as to float the blue filter portion 15B. Furthermore, although not illustrated, since the blue filter portion 15B is located on the upper side of the red filter portion 15R in the overlapping of the peripheral edges in the horizontal direction D_{H}, stress is also likely to be applied to the blue filter portion 15B from the red filter portion 15R in such a direction as to float the blue filter portion 15B. When stress is applied to the blue filter portion 15B in this manner, a cavity 151 starts to be formed between the blue filter portion 15B and the flattening layer 14 below the blue filter portion 15B. As illustrated in FIG. 9, the cavity 151 is filled with the thermosetting resin having penetrated the color filter 15F, and the thermosetting resin filled in the cavity 151 together with the thermosetting resin included in the filling resin layer 16 is cured. As a result, the color filter 15F and the counter substrate 17 are bonded to each other with the filling resin layer 16 interposed therebetween to seal the display device 10, and a layer or the like of the transparent resin 150 is formed on the bottom of the blue filter portion 15B. Note that, in the above description, the phenomena illustrated in FIGS. 7 to 9 have been separately described in order to facilitate understanding, but the phenomena illustrated in FIGS. 7 to 9 may proceed simultaneously. As described above, the display device 10 illustrated in FIGS. 1 to 3 is obtained.

### [Action and Effect]

The OCCF is formed above the light emitting layer which is weak against heat. Accordingly, there is a process restriction that the OCCF is required to be formed by a low-temperature process. Therefore, the conventional display device has a problem that sufficient heat treatment cannot be performed in a process of forming the OCCF, adhesion between the OCCF and a lower layer (for example, a flattening layer, a protective layer, or the like) of the OCCF is deteriorated, and the OCCF is easily peeled off. If peeling occurs, there is a possibility that display characteristics (for example, uniformity, chromaticity, viewing angle, roughness of a display surface, and the like) are deteriorated. Depending on the type and degree of the abnormality of the display characteristics, there is a possibility that reliability (for example, an image defect or the like due to a progress of peeling of the OCCF) is deteriorated.

In the display device 10 according to the first embodiment, the filter portion 15 of at least one color of the red filter portion 15R, the green filter portion 15G, or the blue filter portion 15B includes the transparent resin 150 at the bottom. As a result, the color filter 15F and the flattening layer 14 to be a lower layer of the color filter 15F can be bonded to each other by the transparent resin 150, so that peeling of the color filter 15F can be suppressed. It is therefore possible to suppress a deterioration of the display characteristics. In addition, since having transparency to visible light, the transparent resin 150 can suppress a decrease in luminance of the display device 10.

In the method of manufacturing the display device 10 according to the first embodiment, the transparent resin 150 at the bottom of the filter portion 15 is formed by allowing the thermosetting resin for forming the filling resin layer 16 to penetrate the color filter 15F, filling the cavity 151 formed at the bottom of the filter portion 15, and curing the thermosetting resin in the baking step. Therefore, by formation of the cavity 151, a layer or the like of the transparent resin 150 can be formed in a portion that is easily peeled off.

In the method of manufacturing the display device 10 according to the first embodiment, a layer or the like of the transparent resin 150 can be formed at the bottom of the filter portion 15 in the baking step (sealing step) of thermally curing the filling resin layer 16. Therefore, peeling of the color filter 15F can be suppressed without increasing a manufacturing step.

As described above, since there is a process restriction that the OCCF is required to be formed by the low-temperature process, the conventional display device has a problem that adhesion between the OCCF and a lower layer of the OCCF (for example, a flattening layer or a protective layer) is deteriorated, and the OCCF is easily peeled off. As a method of suppressing peeling of the OCCF, (1) a method of increasing an installation area of the OCCF and the base layer, and (2) a method of increasing the overlapping (overlapping) of the peripheral edges of the adjacent filter portions can be considered. In the method (2), the overlapping width W of the filter portions is preferably 0.1 μm or more and 0.5 μm or less. In recent years, it is desired to increase the definition of the display device, and thus, it is desirable to suppress peeling of the OCCF by the method (2) of the above two methods. However, when the method of (2) is adopted, then, the OCCF is easily peeled off by the stress itself of the filter portions due to overlapping.

On the other hand, in the display device 10 according to one embodiment, since the color filter 15F and the flattening layer 14 to be a lower layer of the color filter 15F are bonded to each other by the transparent resin 150, it is possible to suppress peeling of the color filter 15F even in a case where the overlapping width W of the filter portion 15 exceeds 0.5 μm.

### 2. Second Embodiment

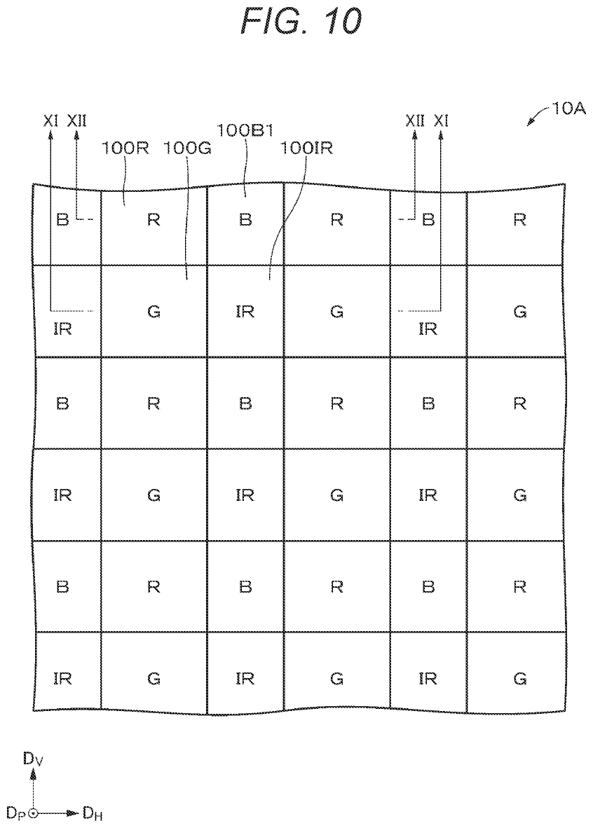

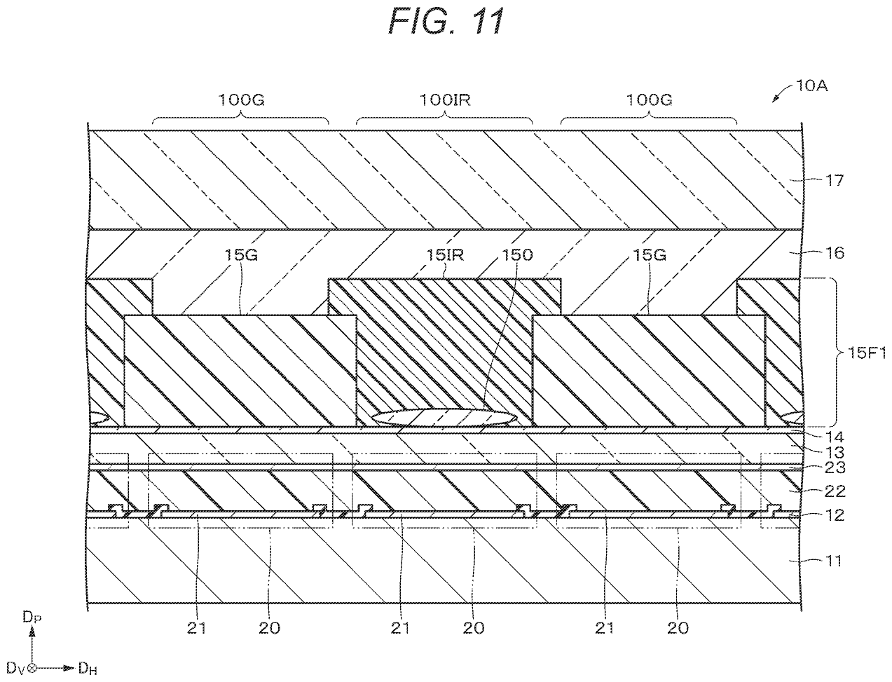

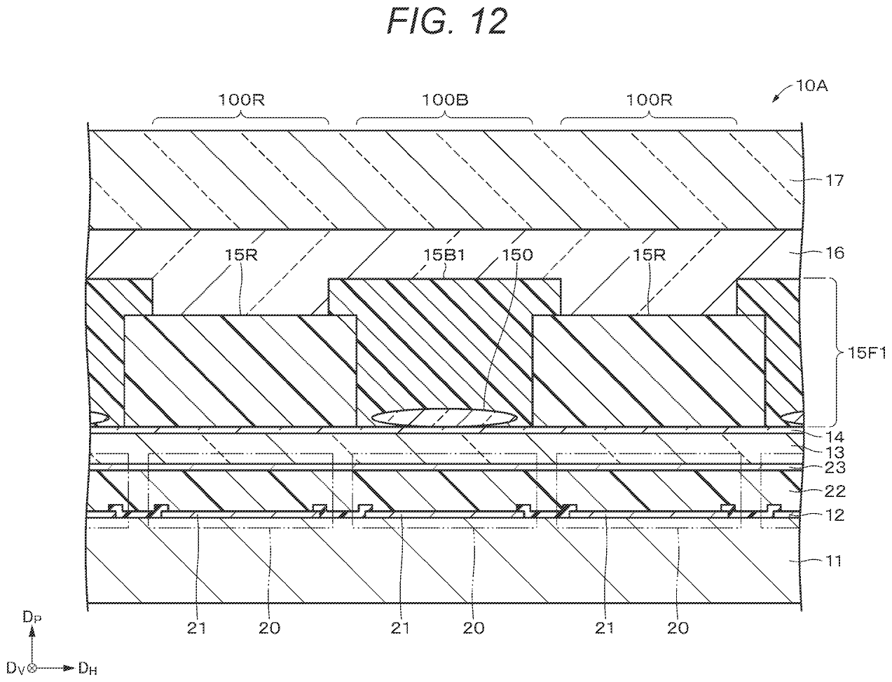

FIG. 10 is an enlarged plan view illustrating a part of a display region R1 of a display device 10A according to a second embodiment. FIG. 11 is a sectional view taken along line XI-XI of FIG. 10. FIG. 12 is a sectional view taken along line XII-XII of FIG. 10. The display device 10A is different from the display device 10 according to the first embodiment in that a plurality of subpixels 100R, 100G, 100B1, and 100IR are configured by a combination of a color filter 15F1 and the light emitting element 20 instead of the plurality of subpixels 100R, 100G, and 100B (see FIGS. 2 to 4) being configured by a combination of the color filter 15F and the light emitting element 20. Note that, in the second embodiment, same reference signs are given to parts similar to those of the first embodiment, and the description thereof will be omitted. In FIG. 10, sections denoted by symbols “R”, “G”, “B”, and “IR” represent the subpixel 100R, the subpixel 100G, the subpixel 100B1, and the subpixel 100IR, respectively.

### (Subpixels 100B1 and 100IR)

The subpixels 100B1 can emit blue light. The subpixels 100B1 have a dot shape. The subpixels 100IR have, for example, a quadrangular shape such as a rectangular shape in plan view.

The subpixels 100IR can emit an infrared ray. The subpixels 100IR have a dot shape. The subpixels 100IR have, for example, a quadrangular shape such as a rectangular shape in plan view.

The subpixels 100B1 and 100IR are alternately arranged in the vertical direction D_{V}, and constitute a column of the subpixels 100B1 and 100IR. The subpixels 100R and 100G are alternately arranged in the vertical direction D_{V}, and constitute a column of the subpixels 100R and 100G. A column including the subpixels 100B1 and 100IR and a column including the subpixels 100R and 100G are alternately arranged in the horizontal direction D_{H}.

The subpixels 100B1 and 100R are alternately arranged in the horizontal direction Du, and constitute a row of the subpixels 100B1 and 100R. The subpixels 100IR and 100G are alternately arranged in the horizontal direction D_{H}, and constitute a row of the subpixels 100IR and 100G. A row including the subpixels 100B1 and 100R and a row including the subpixels 100IR and 100G are alternately arranged in the vertical direction D_{V}.

### (Color Filter 15F1)

The color filter 15F1 includes, for example, a plurality of red filter portions 15R, a plurality of green filter portions 15G, a plurality of blue filter portions 15B1, and a plurality of infrared transmission filter portions 15IR. Note that, in the second embodiment, in a case where collectively referred to without being distinguished from one another, the red filter portions 15R, the green filter portions 15G, the blue filter portions 15B1, and the infrared transmission filter portions 15IR will be collectively referred to as filter portions 15.

The plurality of filter portions 15 is two-dimensionally arranged in an in-plane direction. Each filter portion 15 is provided above one of the light emitting elements 20. The subpixel 100B1 includes the blue filter portion 15B1 and the light emitting element 20. The subpixel 100IR includes the infrared transmission filter portion 15IR and the light emitting element 20. In the second embodiment, the white light emitted from the light emitting elements 20 includes infrared light (infrared ray (IR)).

The blue filter portions 15B1 transmit blue light out of the white light emitted from the light emitting elements 20 and absorb light other than the blue light. The infrared transmission filter portions 15IR transmit infrared light out of the white light emitted from the light emitting elements 20 and absorb light other than the infrared light.

Similarly to the subpixel 100B1 and the subpixel 100IR, the blue filter portion 15B1 and the infrared transmission filter portion 15IR have a dot shape in plan view. The blue filter portion 15B1 and the infrared transmission filter portion 15IR have, for example, a quadrangular shape such as a rectangular shape in plan view.

The filter portion 15 of at least one color of the blue filter portion 15B1, the green filter portion 15G, the red filter portion 15R, or the infrared transmission filter portion 15IR includes a transparent resin 150 at the bottom of the filter portion 15. Specifically, for example, one filter portion 15 of the blue filter portion 15B1, the green filter portion 15G, the red filter portion 15R, or the infrared transmission filter portion 15IR may include the transparent resin 150 at the bottom of the filter portion 15, two filter portions 15 of the blue filter portion 15B1, the green filter portion 15G, the red filter portion 15R, or the infrared transmission filter portion 15IR may include the transparent resin 150 at the bottom of the filter portion 15, three filter portions 15 of the blue filter portion 15B1, the green filter portion 15G, the red filter portion 15R, or the infrared transmission filter portion 15IR may include the transparent resin 150 at the bottom of the filter portion 15, and all of the blue filter portion 15B1, the green filter portion 15G, the red filter portion 15R, and the infrared transmission filter portion 15IR may include the transparent resin 150 at the bottom of the filter portion 15. FIGS. 11 and 12 illustrate an example in which the infrared transmission filter portion 15IR includes the transparent resin 150 at the bottom of the infrared transmission filter portion 15IR, and the blue filter portion 15B1 includes the transparent resin 150 at the bottom of the blue filter portion 15B1.

Peripheral edges of the adjacent filter portion 15 may overlap each other. The filter portion 15 located on the upper side in the overlapping of the peripheral edges preferably includes the transparent resin 150 at the bottom.

For example, as illustrated in FIG. 11, the peripheral edge of the infrared transmission filter portion 15IR and the peripheral edge of the green filter portion 15G may overlap each other in the horizontal direction D_{H}. The peripheral edge of the infrared transmission filter portion 15IR may be located on the upper side of the peripheral edge of the green filter portion 15G in the horizontal direction D_{H}. In this case, the peripheral edge of infrared transmission filter portion 15IR preferably includes the transparent resin 150 at the bottom. Alternatively, the peripheral edge of the green filter portion 15G may be located on the upper side of the peripheral edge of the infrared transmission filter portion 15IR in the horizontal direction DA. In this case, the peripheral edge of green filter portion 15G preferably includes the transparent resin 150 at the bottom.

For example, as illustrated in FIG. 12, the peripheral edge of the blue filter portion 15B1 and the peripheral edge of the red filter portion 15R may overlap each other in the horizontal direction DA. The peripheral edge of the blue filter portion 15B1 may be located on the upper side of the peripheral edge of the red filter portion 15R in the horizontal direction DA. In this case, the peripheral edge of the blue filter portion 15B1 preferably includes the transparent resin 150 at the bottom.

For example, the peripheral edge of the red filter portion 15R and the peripheral edge of the green filter portion 15G may overlap each other in the vertical direction D_{V}. The peripheral edge of the red filter portion 15R may be located on the upper side of the peripheral edge of the green filter portion 15G in the vertical direction D_{V}. In this case, the peripheral edge of the red filter portion 15R preferably includes the transparent resin 150 at the bottom.

For example, the peripheral edge of the blue filter portion 15B1 and the peripheral edge of the infrared transmission filter portion 15IR may overlap each other in the vertical direction D_{V}. The peripheral edge of the blue filter portion 15B1 may be located on the upper side of the peripheral edge of the infrared transmission filter portion 15IR in the vertical direction D_{V}. In this case, the peripheral edge of the blue filter portion 15B1 preferably includes the transparent resin 150 at the bottom. Alternatively, the peripheral edge of the infrared transmission filter portion 15IR may be located on the upper side of the peripheral edge of the blue filter portion 15B1 in the vertical direction D_{V}. In this case, the peripheral edge of infrared transmission filter portion 15IR preferably includes the transparent resin 150 at the bottom.

The blue filter portion 15B1 includes, for example, a blue colorant and an ultraviolet curable resin. The blue colorant includes, for example, at least one selected from the group consisting of a blue dye and a blue pigment. The infrared transmission filter portion 15IR includes, for example, an infrared transmitting black color material and an ultraviolet curable resin.

### [Action and Effect]

In the display device 10A according to the second embodiment, the filter portion 15 of at least one type of the red filter portion 15R, the green filter portion 15G, the blue filter portion 15B1, or the infrared transmission filter portion 15IR includes the transparent resin 150 at the bottom. As a result, the color filter 15F and the flattening layer 14 to be a lower layer of the color filter 15F can be bonded to each other by the transparent resin 150, so that peeling of the color filter 15F1 can be suppressed.

In the display device 10A according to the second embodiment, since one pixel includes the subpixel 100IR in addition to the subpixels 100R, 100G, and 100B1 of three primary colors, the function of the display device 10A can be improved. Therefore, it is possible to improve the function of the display device 10A while suppressing peeling of the color filter 15F1.

### 3 Third Embodiment

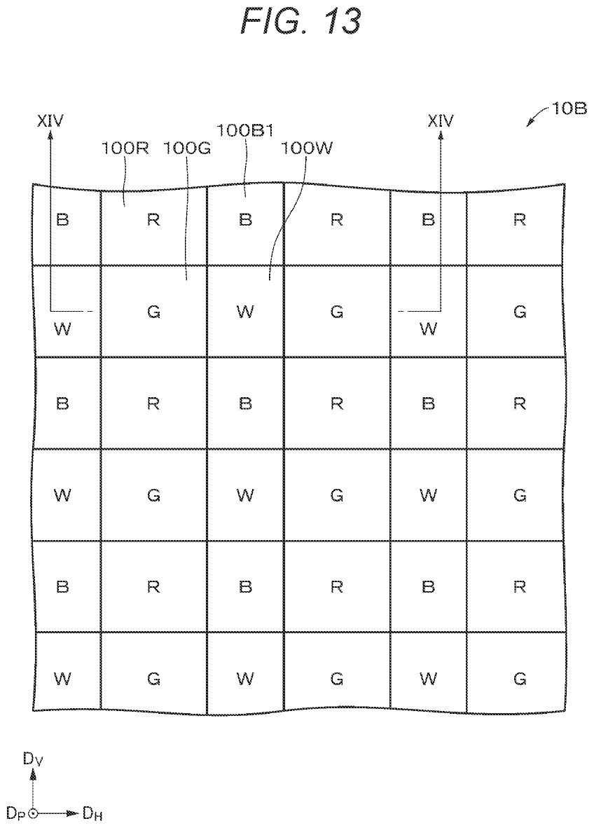

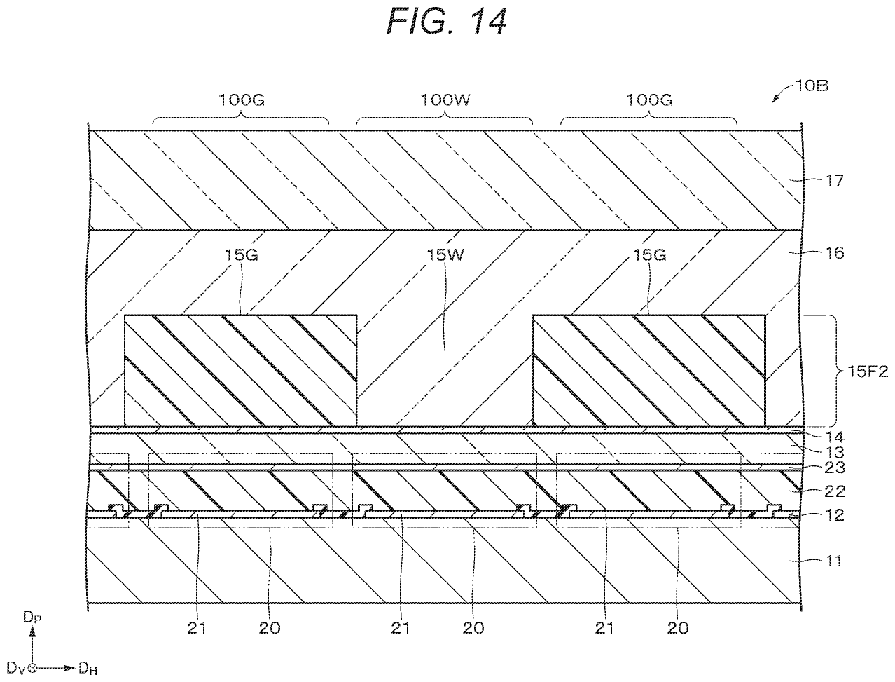

FIG. 13 is an enlarged plan view illustrating a part of a display region R1 of a display device 10B according to a third embodiment. FIG. 14 is a sectional view taken along line XIV-XIV of FIG. 13. The display device 10B is different from the display device 10A according to the second embodiment in that a plurality of subpixels 100R, 100G, 100B1, and 100W are configured by a combination of a color filter 15F2 and the light emitting element 20 instead of the plurality of subpixels 100R, 100G, 100B1, and 100IR (see FIGS. 10 to 12) being configured by a combination of the color filter 15F1 and the light emitting element 20. Note that, in the third embodiment, same reference signs are given to parts similar to those of the second embodiment, and the description thereof will be omitted. In FIG. 13, sections denoted by symbols “R”, “G”, “B”, and “W” represent the subpixel 100R, the subpixel 100G, the subpixel 100B1, and the subpixel 100W, respectively.

### (Subpixel 100W)

The subpixels 100W can emit white light. The subpixels 100W have a dot shape. The subpixels 100W have, for example, a quadrangular shape such as a rectangular shape in plan view.

The subpixels 100B1 and 100W are alternately arranged in the vertical direction D_{V}, and constitute a column of the subpixels 100B1 and 100W. The subpixels 100R and 100G are alternately arranged in the vertical direction D_{V}, and constitute a column of the subpixels 100R and 100G. A column including the subpixels 100B1 and 100W and a column including the subpixels 100R and 100G are alternately arranged in the horizontal direction D_{H}.

The subpixels 100B1 and 100R are alternately arranged in the horizontal direction D_{H}, and constitute a row of the subpixels 100B1 and 100R. The subpixels 100W and 100G are alternately arranged in the horizontal direction D_{H}, and constitute a row of the subpixels 100w and 100G. A row including the subpixels 100B1 and 100R and a row including the subpixels 100W and 100G are alternately arranged in the vertical direction D_{V}.

### (Color Filter 15F2)

The color filter 15F2 includes, for example, a plurality of red filter portions 15R, a plurality of green filter portions 15G, a plurality of blue filter portions 15B1, and a plurality of light transmitting portions 15W. Note that, in the third embodiment, in a case where collectively referred to without being distinguished from one another, the red filter portions 15R, the green filter portions 15G, and the blue filter portions 15B1 will be collectively referred to as filter portions 15.

The plurality of filter portions 15 and the plurality of light transmitting portions 15W are two-dimensionally arranged in an in-plane direction. Each filter portion 15 is provided above one of the light emitting elements 20. Each light transmitting portion 15W is provided above one of the light emitting elements 20. The subpixel 100W includes the light transmitting portion 15W and the light emitting element 20.

The light transmitting portion 15W can transmit white light emitted from the light emitting element 20. The light transmitting portion 15W is, for example, an opening penetrating in the perpendicular direction D_{P}.

The light transmitting portion 15W has a dot shape in plan view, similarly to the subpixels 100R, 100G, and 100B1. The light transmitting portion 15W has, for example, a quadrangular shape such as a rectangular shape in plan view.

The filter portion 15 of at least one color of the red filter portion 15R, the green filter portion 15G, or the blue filter portion 15B1 includes a transparent resin 150 at a bottom of the filter portion 15. Specifically, for example, the filter portion 15 of one color of the red filter portion 15R, the green filter portion 15G, or the blue filter portion 15B1 may include the transparent resin 150 at the bottom of the filter portion 15, the filter portions 15 of two colors of the red filter portion 15R, the green filter portion 15G, or the blue filter portion 15B1 may include the transparent resin 150 at the bottom of the filter portion 15, and all of the red filter portion 15R, the green filter portion 15G, and the blue filter portion 15B1 may include the transparent resin 150 at the bottom of the filter portion 15.

### [Action and Effect]

In the display device 10B according to the third embodiment, the filter portion 15 of at least one type of the red filter portion 15R, the green filter portion 15G, or the blue filter portion 15B1 includes the transparent resin 150 at the bottom. As a result, the color filter 15F2 and the flattening layer 14 to be a lower layer of the color filter 15F2 can be bonded to each other by the transparent resin 150, so that peeling of the color filter 15F2 can be suppressed.

In the display device 10B according to the third embodiment, since one pixel includes the subpixel 100W in addition to the subpixels 100R, 100G, and 100B1 of three primary colors, the luminance of the display device 10B can be improved. Therefore, it is possible to improve the luminance of the display device 10B while suppressing peeling of the color filter 15F2.

### 4. Modifications

### (Modification 1)

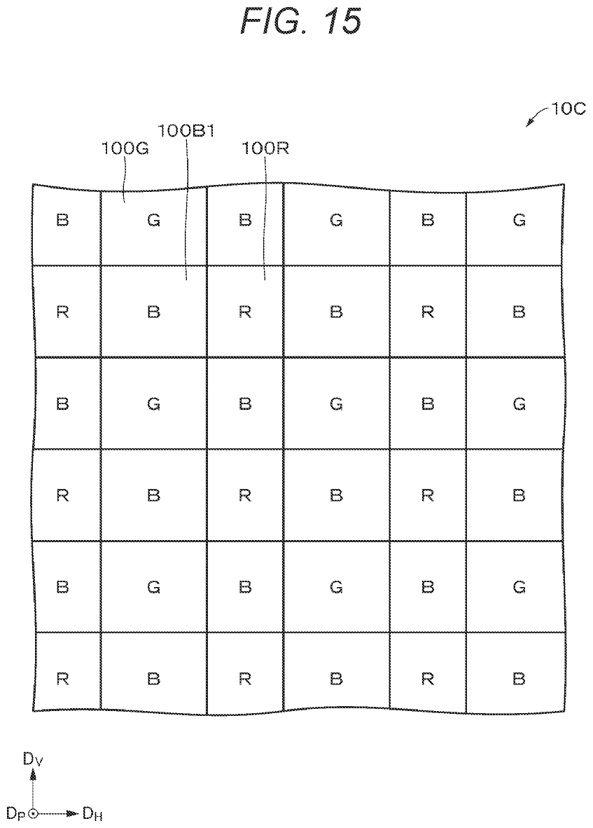

FIG. 15 is an enlarged plan view illustrating a part of a display region R1 of a display device 10C according to Modification 1. The display device 10C is different from the display device 10 according to the second embodiment in that one pixel includes a combination of the four subpixels 100R, 100G, 100B1, and 100B1. The subpixels 100G and 100B1 are alternately arranged in the vertical direction D_{V}, and constitute a column of the subpixels 100G and 100B1. The subpixels 100B1 and 100R are alternately arranged in the vertical direction D_{V}, and constitute a column of the subpixels 100B1 and 100R. A column including the subpixels 100G and 100B1 and a column including the subpixels 100B1 and 100R are alternately arranged in the horizontal direction D_{H}. The subpixels 100G and 100B1 are alternately arranged in the horizontal direction D_{H}, and constitute a row of the subpixels 100G and 100B1. The subpixels 100B1 and 100R are alternately arranged in the horizontal direction DA, and constitute a row of the subpixels 100B1 and 100R. A row including the subpixels 100G and 100B and a row including the subpixels 100B1 and 100R are alternately arranged in the vertical direction D_{V}.

### (Modification 2)

In the first embodiment, an example has been described in which the subpixels 100R and 100G have a quadrangular shape in plan view and the subpixel 100B has a linear shape in plan view, but the shapes of the subpixels 100R, 100G, and 100B are not limited to this example.

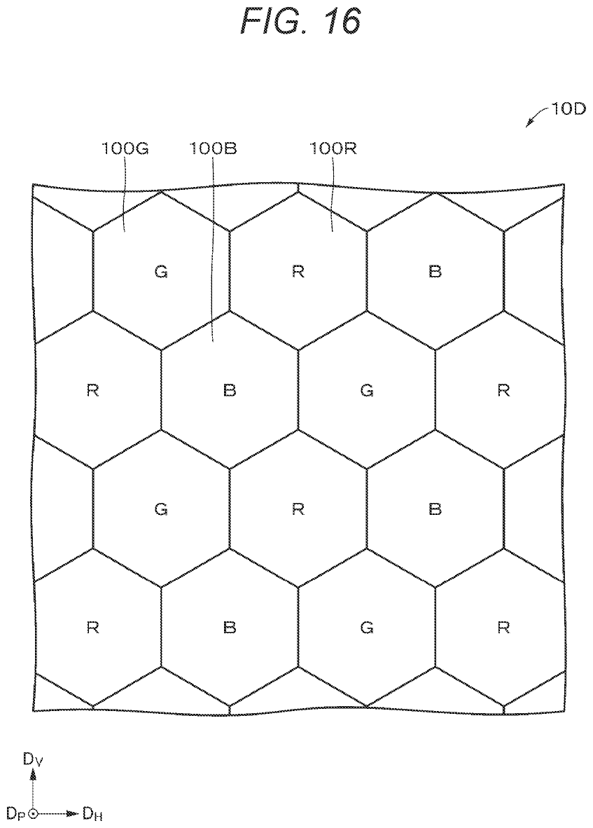

FIG. 16 is an enlarged plan view illustrating a part of a display region R1 of a display device 10D according to Modification 2. The display device 10D is different from the display device according to the first embodiment in that the subpixels 100R, 100G, and 100B have a hexagonal shape in plan view. Although not illustrated, the subpixels 100R, 100G, and 100B may have a circular shape or an elliptical shape in plan view, or may have a polygonal shape other than a quadrangular shape and a hexagonal shape in plan view.

### (Modification 3)

In the first to third embodiments, an example has been described in which one pixel includes three subpixels 100 or four subpixels 100, but the configuration of one pixel is not limited to this example. For example, one pixel may include two subpixels 100 or five or more subpixels 100. In this case, the color filter may include filter portions of two colors or filter portions of five or more colors.

### (Modification 4)

In the third embodiment, an example has been described in which the color filter 15F2 includes the light transmitting portion 15W and the light transmitting portion 15W is an opening, but the light transmitting portion 15W may be a transparent filter portion. The transparent filter portion has transparency to visible light. The transparent filter portion includes, for example, an ultraviolet curable resin.

In a case where the light transmitting portion 15W is a transparent filter portion, the filter portion 15 of at least one type of the red filter portion 15R, the green filter portion 15G, the blue filter portion 15B1, or the transparent filter portion may include the transparent resin 150 at the bottom.

### (Modification 5)

In the first to third embodiments, an example has been described in which the color filters 15F, 15F1, and 15F2 are provided on the first surface of the flattening layer 14. However, the color filters 15F, 15F1, and 15F2 may be provided on the first surface of the protective layer 13 or may be provided on a layer other than the flattening layer 14 and the protective layer 13. The layer other than the flattening layer 14 and the protective layer 13 may be an organic layer or an inorganic layer.

### (Modification 6)

In the first embodiment, a method using the white OLED element and the color filter 15F has been described, but a method using a monochromatic OLED element such as a red OLED element, a green OLED element, or a blue OLED element and a color filter may be used. In this case, the color filter may be used for applications such as antireflection. The color filter may be a monochromatic filter, may include a filter portion of two or three or more colors, or may be the color filter 15F according to one embodiment.

### (Modification 7)

In the first embodiment, an example has been described in which the color filter 15F includes the plurality of red filter portions 15R, the plurality of green filter portions 15G, and the plurality of blue filter portions 15B. However, the configuration of the color filter 15F is not limited to this example. For example, the color filter 15F may further include at least one of a plurality of cyan filter portions or a plurality of magenta filter portions in addition to the plurality of red filter portions 15R, the plurality of green filter portions 15G, and the plurality of blue filter portions 15B. The cyan filter portion and the magenta filter portion are complementary color filters for adjusting color light of the subpixels 100R, 100G, and 100B.

Note that, in the second embodiment, the color filter 15F1 may further include at least one of a plurality of cyan filter portions or a plurality of magenta filter portions. In addition, in the third embodiment, the color filter 15F2 may further include at least one of a plurality of cyan filter portions or a plurality of magenta filter portions.

### (Modification 8)

In the first embodiment, an example has been described in which the cavity 151 is formed by an overlap design between the adjacent filter portions 15 (stress between the adjacent filter portions 15). However, the cavity 151 may be formed by a pixel pitch of the subpixels 100, a combination of materials of the color filter 15F and the lower layer of the color filter 15F, a material of the filling resin layer 16, a process condition at the time of sealing by the counter substrate 17, or the like. The cavity 151 may be formed by a combination of the above two or more conditions.

### (Other Modifications)

Although the first to third embodiments of the present disclosure and modifications thereof have been specifically described above, the present disclosure is not limited to the above-described first to third embodiments and modifications thereof, and various modifications based on the technical idea of the present disclosure are possible.

For example, the configurations, methods, steps, shapes, materials, numerical values, and the like mentioned in the above-described first to third embodiments and modifications thereof are merely examples, and different configurations, methods, steps, shapes, materials, numerical values, and the like may be used as necessary.

For example, the configurations, methods, steps, shapes, materials, numerical values, and the like of the above-described first to third embodiments and modifications thereof can be combined with each other without departing from the gist of the present disclosure.

For example, the materials exemplified in the above-described first to third embodiments and modifications thereof can be used alone or in combination of two or more unless otherwise specified.

Furthermore, the present disclosure can also adopt the following configurations.

(1)

A light emitting device including
a plurality of light emitting elements arranged two-dimensionally, and
a filter provided above the plurality of light emitting elements and including filter portions of a plurality of colors, in which
the filter portion of at least one color of the filter portions of the plurality of colors includes a transparent resin at a bottom of the filter portion.
   (2)

The light emitting device according to (1), in which the transparent resin includes a thermosetting resin.

(3)

The light emitting device according to (1), in which the transparent resin includes an epoxy resin.

(4)

The light emitting device according to any one of (1) to (3)
further including a resin layer provided on the filter, in which
the transparent resin and the resin layer include materials of the same component.
   (5)

The light emitting device according to (1)
further including a resin layer provided on the filter, in which
the transparent resin and the resin layer include a thermosetting resin.
   (6)

The light emitting device according to (1)
further including a resin layer provided on the filter, in which
the transparent resin and the resin layer include an epoxy resin.
   (7)

The light emitting device according to any one of (1) to (6), in which peripheral edges of the filter portions being adjacent overlap each other.

(8)

The light emitting device according to (7), in which the filter portion located on an upper side in overlapping of the peripheral edges includes the transparent resin at the bottom.

(9)

The light emitting device according to any one of (1) to (8), in which the filter portions of the plurality of colors include a plurality of red filter portions, a plurality of green filter portions, and a plurality of blue filter portions.

(10)

The light emitting device according to (9), in which the filter further includes a plurality of infrared transmission filter portions.

(11)

The light emitting device according to (9), in which
the plurality of light emitting elements can emit white light,
the filter further includes a plurality of light transmitting portions, and
the light transmitting portions can transmit the white light.
   (12)

The light emitting device according to any one of (1) to (11), in which the transparent resin exists in a part of the bottom.

(13)

The light emitting device according to any one of (1) to (11), in which the transparent resin exists in a substantial entirety of the bottom.

(14)

The light emitting device according to any one of (1) to (13), in which the transparent resin has a layer shape.

(15)

The light emitting device according to any one of (1) to (14), in which the transparent resin has a granular shape.

(16)

A light emitting device including
a plurality of light emitting elements arranged two-dimensionally, and
a filter provided above the plurality of light emitting elements, in which
the filter includes a filter portion including a transparent resin at a bottom of the filter portion.
   (17)

An electronic apparatus including the light emitting device according to any one of (1) to (16).

### 5 Application Examples

### (Electronic Apparatus)

The display devices 10, 10A, 10B, 10C, and 10D (hereinafter referred to as “display device 10 and the like”) according to the above-described first to third embodiments and modifications thereof can be used for various electronic apparatuses. The display device 10 and the like are suitable especially for an electronic view finder of a video camera or a single-lens reflex camera, a head-mounted display, or the like requiring high resolution and used near the eyes in an enlarged manner.

### Specific Example 1

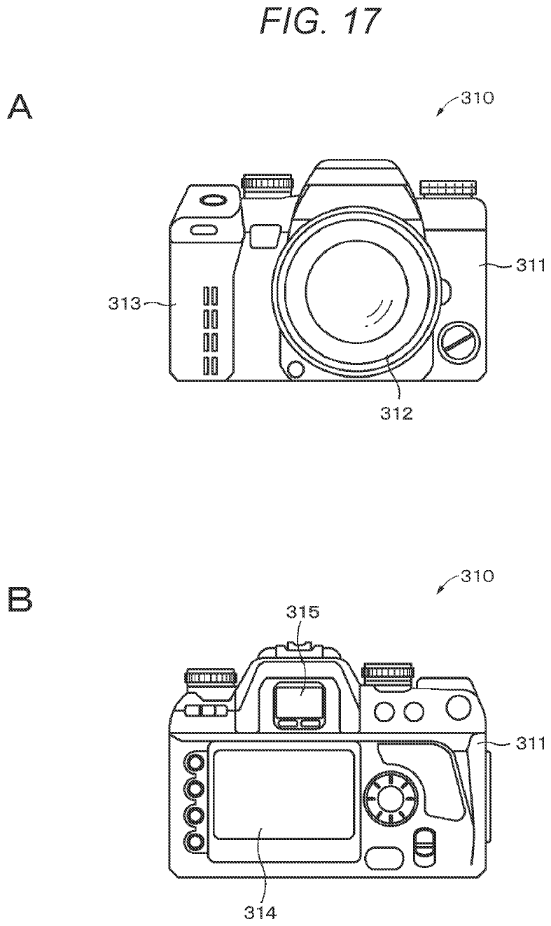

FIGS. 17A and 17B illustrate an example of an external appearance of a digital still camera 310. The digital still camera 310 is of a lens interchangeable single-lens reflex type, and includes an interchangeable imaging lens unit (interchangeable lens) 312 substantially at the center on a front surface of a camera main body (camera body) 311, and a grip 313 to be held by a photographer on a front left side.

A monitor 314 is provided at a position shifted to the left side from the center of a rear surface of the camera main body 311. An electronic view finder (eyepiece window) 315 is provided above the monitor 314. By looking through the electronic view finder 315, the photographer can visually confirm an optical image of a subject guided from the imaging lens unit 312 and determine a picture composition. The electronic view finder 315 includes any one of the display device 10 and the like.

### Specific Example 2

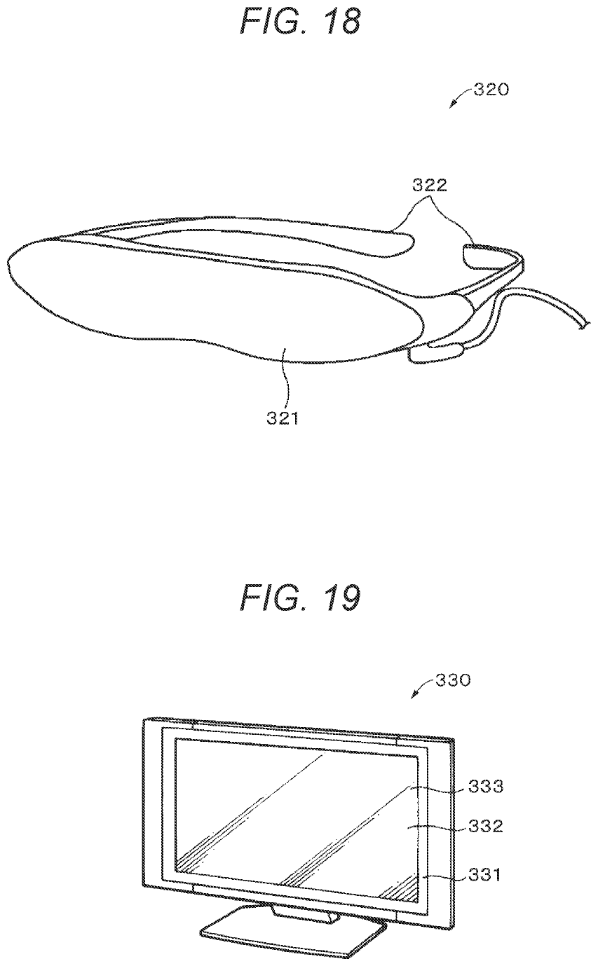

FIG. 18 illustrates an example of an external appearance of a head mounted display 320. The head mounted display 320 includes, for example, ear hooks 322 to be worn on the head of the user on both sides of a glass-shaped display unit 321. The display unit 321 includes any one of the display device 10 and the like.

### Specific Example 3

FIG. 19 illustrates an example of an external appearance of a television apparatus 330. The television apparatus 330 includes, for example, a video display screen 331 including a front panel 332 and a filter glass 333, and the video display screen 331 includes any one of the display device 10 and the like.

### REFERENCE SIGNS LIST

10, 10A, 10B, 10C, 10D Display device
11 Circuit substrate
11a Pad
12 Insulating layer
13 Protective layer
14 Flattening layer
15F, 15F1, 15F2 Color filter
15R Red filter portion
15G Green filter portion
15B, 15B1 Blue filter portion
15IR Infrared transmission filter portion
15W Light transmitting portion
16 Filling resin layer
17 Counter substrate
20 Light emitting element
21 First electrode
22 OLED layer
23 Second electrode
R1 Display region
R2 Peripheral region
100R, 100G, 100B, 100B1, 100W, 100IR Subpixel
150 Transparent resin
151 Cavity
310 Digital still camera (electronic apparatus)
320 Head mounted display (electronic apparatus)
330 Television apparatus (electronic apparatus)
D_{P} Direction perpendicular to display surface (perpendicular direction)
D_{H} Horizontal direction
D_{V} Vertical direction

1. A light emitting device, comprising:
a plurality of light emitting elements arranged two-dimensionally; and
a filter provided above the plurality of light emitting elements and including filter portions of a plurality of colors, wherein
the filter portion of at least one color of the filter portions of the plurality of colors includes a transparent resin at a bottom of the filter portion.

2. The light emitting device according to claim 1, wherein the transparent resin includes a thermosetting resin.

3. The light emitting device according to claim 1, wherein the transparent resin includes an epoxy resin.

4. The light emitting device according to claim 1,
further comprising a resin layer provided on the filter, wherein
the transparent resin and the resin layer include materials of a same component.

5. The light emitting device according to claim 1,
further comprising a resin layer provided on the filter, wherein
the transparent resin and the resin layer include a thermosetting resin.

6. The light emitting device according to claim 1,
further comprising a resin layer provided on the filter, wherein
the transparent resin and the resin layer include an epoxy resin.

7. The light emitting device according to claim 1, wherein peripheral edges of the filter portions being adjacent overlap each other.

8. The light emitting device according to claim 7, wherein the filter portion located on an upper side in overlapping of the peripheral edges includes the transparent resin at the bottom.

9. The light emitting device according to claim 1, wherein the filter portions of the plurality of colors include a plurality of red filter portions, a plurality of green filter portions, and a plurality of blue filter portions.

10. The light emitting device according to claim 9, wherein the filter further includes a plurality of infrared transmission filter portions.

11. The light emitting device according to claim 9, wherein
the plurality of light emitting elements can emit white light,
the filter further includes a plurality of light transmitting portions, and
the light transmitting portions can transmit the white light.

12. The light emitting device according to claim 1, wherein the transparent resin exists in a part of the bottom.

13. The light emitting device according to claim 1, wherein the transparent resin exists in a substantial entirety of the bottom.

14. The light emitting device according to claim 1, wherein the transparent resin has a layer shape.

15. The light emitting device according to claim 1, wherein the transparent resin has a granular shape.

16. A light emitting device comprising:
a plurality of light emitting elements arranged two-dimensionally; and
a filter provided above the plurality of light emitting elements, wherein
the filter includes a filter portion including a transparent resin at a bottom of the filter portion.

17. An electronic apparatus comprising the light emitting device according to claim 1.
